(19) United States
(12) Patent Application Publication
(10) Pub. No.: US 2025/0316444 A1
(43) Pub. Date: Oct. 9, 2025

(54) RADIATION TOLERANT DETECTOR ARCHITECTURE FOR CHARGED PARTICLE DETECTION

(71) Applicant: ASML Netherlands B.V., Veldhoven (NL)

(72) Inventors: Jan BEX, Pelt (BE); Bernd Michael VOLLMER, Dresden (DE); Harald Gert Helmut NEUBAUER, Erlangen (DE); Matthias OBERST, Nürnberg (DE); Hindrik Willem MOOK, The Hague (NL); Utku ULUDAG, Delft (NL); Thomas SCHWEIGER, Nueremberg (DE)

(73) Assignee: ASML Netherlands B.V., Veldhoven (NL)

(21) Appl. No.: 18/863,148

(22) PCT Filed: Apr. 10, 2023
(86) PCT No.: PCT/EP2023/059349

§ 371 Date: Nov. 5, 2024

Related U.S. Application Data
(60) Provisional application No. 63/338,758, filed on May 5, 2022.

(51) Int. Cl. H01J 37/244

(52) U.S. Cl. CPC H01J 37/244; H01J 2237/2441; H01J 2237/2448; H01J 2237/2806

(57) ABSTRACT

A detector for a scanning electron microscope (SEM) system comprises a semiconductor substrate, and a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.

### CROSS-REFERENCE TO RELATED APPLICATIONS

This application claims priority of U.S. application 63/338,758 which was filed on May 5, 2022 and which is incorporated herein in its entirety by reference.

### TECHNICAL FIELD

The description herein relates to detectors, and more particularly, to detectors that may be applicable to charged particle detection.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. The SEM may comprise detectors that receive charged particles projected from a sample and that output detection signals. Detection signals may be used to reconstruct images of sample structures under inspection and may be used, for example, to reveal defects in the sample.

With continuing miniaturization of semiconductor devices, inspection systems may use lower and lower beam currents in charged particle beam tools. Meanwhile, a detector may require flexibility for detecting multiple beams that may land on the detector with unknown sizes and at unknown positions. A detector array may be pixelated in an array of sensing elements that can adapt to different shapes and sizes of beams. Thereby, a detector can be implemented to include switching elements to activate or deactivate a certain sensing element or to connect pixelated sensing elements that are grouped together depending on the beam(s) landing on the detector. However, recent studies have found that the switching elements included in the detector tend to get damaged after e-beam exposure for a certain period of time, which limiting lifetime of the detector and the SEM tool not to mention the switching element itself.

### SUMMARY

Some embodiments provide a detector for a scanning electron microscope (SEM) system. The detector comprises a semiconductor substrate, and a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.

Some embodiments provide charged-particle inspection system comprising a charged-particle beam source configured to generate a primary charged-particle beam for sample scanning; and a detector configured to receive a secondary charged-particle beam exiting a sample from a point of incidence of the primary charged-particle beam at the sample. The detector comprises a semiconductor substrate, and a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.

It is to be understood that both the foregoing general description and the following detailed description are exemplary and explanatory only and are not restrictive of the disclosed embodiments, as may be claimed.

### BRIEF DESCRIPTION OF DRAWINGS

The above and other aspects of the present disclosure will become more apparent from the description of exemplary embodiments, taken in conjunction with the accompanying drawings.

FIG. 1 is a schematic diagram illustrating an exemplary charged-particle beam inspection system, consistent with embodiments of the present disclosure.

FIG. 2 is a schematic diagram illustrating an exemplary multi-beam tool, consistent with embodiments of the present disclosure that can be a part of the exemplary charged-particle beam inspection system of FIG. 1.

FIG. 3A is a schematic representation of an exemplary structure of a detector, consistent with embodiments of the present disclosure.

FIG. 3B is a diagram illustrating an exemplary surface of a detector array, consistent with embodiments of the present disclosure.

FIG. 4 is a diagram illustrating an exemplary detector array with a switching network, consistent with embodiments of the present disclosure.

FIG. 5A is a diagram illustrating a cross-sectional view of a detector structure, consistent with embodiments of the present disclosure.

FIG. 5B is a diagram illustrating a cross-sectional view of a sensing element of a detector,

consistent with embodiments of the present disclosure.

FIG. 6A is a diagram illustrating a cross-sectional view of a two-die detector configuration, consistent with embodiments of the present disclosure.

FIG. 6B is a diagram illustrating a detector array having a two-die configuration, consistent with embodiments of the present disclosure.

FIG. 7 is a diagram illustrating a top view of an example radiation hardened NMOS transistor, consistent with embodiments of the present disclosure.

FIG. 8A is a diagram illustrating an exemplary detector architecture, consistent with embodiments of the present disclosure.

FIG. 8B is a diagram illustrating another exemplary detector architecture, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing charged-particle beams (e.g., electron beams), the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Electrons exiting a wafer that are received by the detector of the SEM may cause the detector to generate electrical signals (e.g., current signals or voltage signals) commensurate to the energy of the exiting electrons and the intensity of the electron beam. For example, the amplitudes of the electrical signals may be commensurate to the charges of the received exiting electrons. The detector may output the electrical signals to an image processor, and the image processor may process the electrical signals to form the image of structures of the wafer. A multi-beam SEM system uses multiple electron beams for inspection, and a detector of the multi-beam SEM system may have multiple sections to receive them. Each section may have multiple sensing elements and may be used to form a “picture” of a sub-region of the wafer. The “picture” generated based on signals from each section of the detector may be merged to form a complete picture of the inspected wafer.

A detector array may be pixelated in an array of sensing elements that can adapt to different shapes and sizes of beams. Thereby, a detector can be implemented to include switching elements to activate or deactivate a certain sensing element or to connect pixelated sensing elements that are grouped together depending on the beam(s) landing on the detector. Recent studies have found that the switching elements included in the detector tend to get damaged after e-beam exposure for a certain period of time, thereby limiting the lifetime of the detector and the SEM tool not to mention the switching element itself. However, prior to these studies, root causes thereof have not been discovered.

Because the SEM tool is not operated in generally known X-ray radiation environments such as space, military use, or nuclear environment, nobody has anticipated that X-ray exposure could cause damage to the switching elements. However, it has been discovered that X-rays generated during interaction of electrons with the detector, in particular, a sensing element (e.g., PIN diode), may cause damage to switching elements of detectors of a SEM tool. That is, X-ray induced damage to switching elements shorten the lifetime of the detector and deteriorate the overall throughput of the SEM tool. X-ray exposure to switching elements such as transistors (e.g., MOS transistors) can also increase the resistance of the transistors in the on state, resulting in a reduced operating speed of the detector and thus reducing the bandwidth of the detector. Further, when the transistor is exposed to X-rays, the threshold current leakage increases in transistors in the off state.

According to some embodiments of the present disclosure, radiation hardened design techniques can be used in the detector in which switching elements are positioned in proximity to sensing elements. In some embodiments, detectors of a SEM tool can be formed to use radiation hardened transistors only for switching elements. According to some embodiments of the present disclosure, a detector that include switching elements on a different chip from sensing elements can be provided. According to some embodiments of the present disclosure, a detector that does not utilize switching elements can be provided.

Relative dimensions of components in drawings may be exaggerated for clarity. Within the following description of drawings, the same or like reference numbers refer to the same or like components or entities, and only the differences with respect to the individual embodiments are described.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, or the like.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

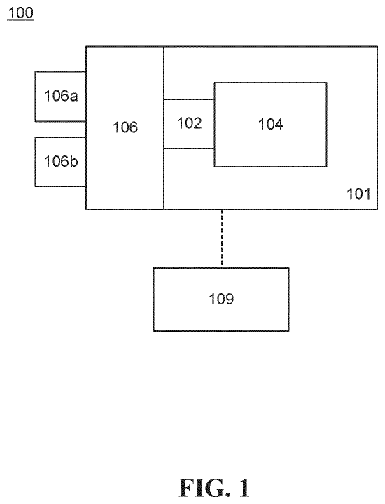

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

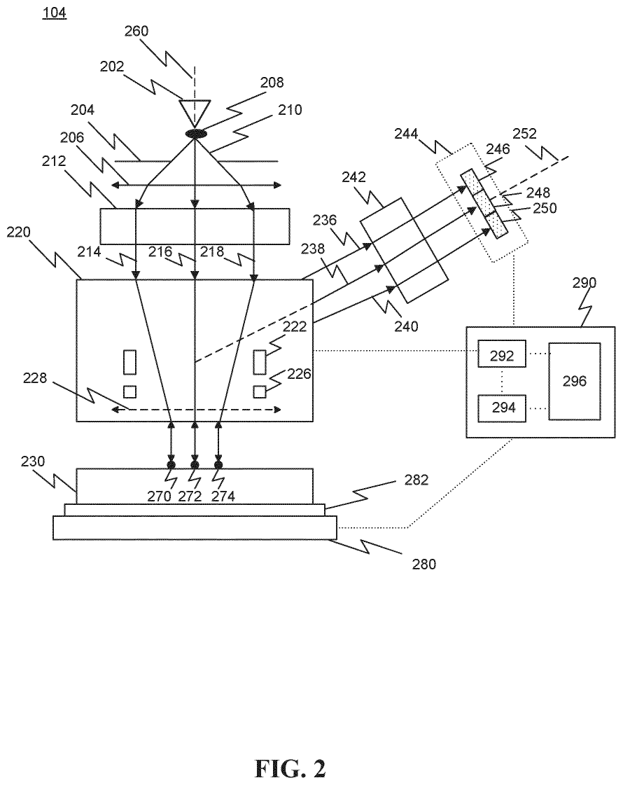

FIG. 2 illustrates a schematic diagram of an exemplary multi-beam beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

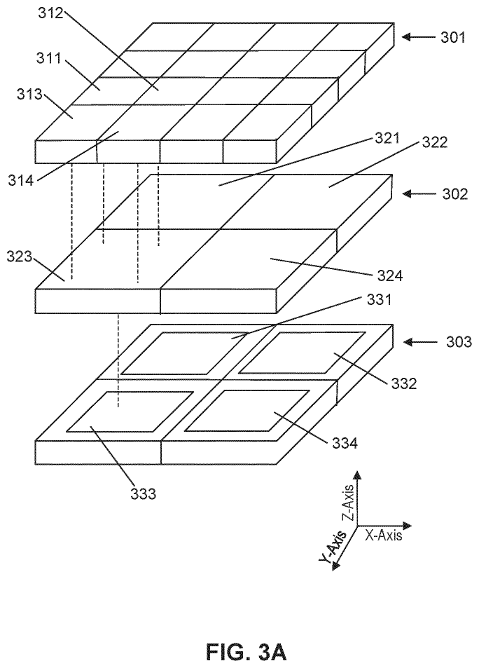

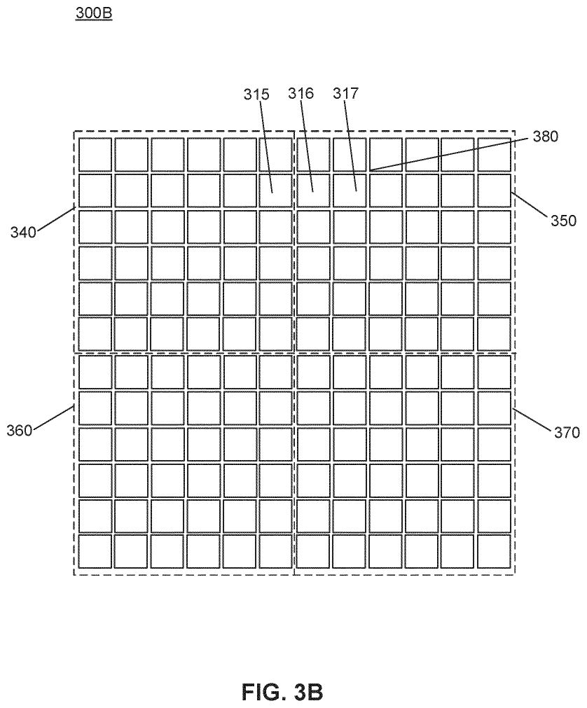

FIG. 3A illustrates a schematic representation of an exemplary structure of a detector 300A, consistent with embodiments of the present disclosure. Detector 300A may be provided as charged-particle detection device 244. In FIG. 3A, detector 300A includes a sensor layer 301, a switching layer 302, and a readout layer 303. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement. Detector 300A may have an arrangement with respect to a coordinate axis reference frame. Sensor layer 301 may be arranged along an x-y plane. Sensing elements in sensor layer 301 may be arrayed in x-axis and y-axis directions. The x-axis direction may also herein be referred to as a “horizontal” direction. The y-axis direction may also herein be referred to as a “vertical” direction. Detector 300A may have a layer structure in which sensor layer 301, switching layer 302, and readout layer 303 are stacked in a z-axis direction. The z-axis direction may also herein be referred to as a “thickness” direction. The z-axis direction may be aligned with a direction of incidence of charged particles that are directed toward detector 300A. While it is described referring to FIG. 3A that sensing elements are arranged in orthogonal grid, it will be appreciated that FIG. 3A is provided as an example and the present disclosure is applicable to sensing elements arranged in any form, e.g., non-orthogonal grid.

Switching layer 302 may include multiple sections, including sections 321, 322, 323, and 324. The sections may include interconnections (e.g., wiring paths) configured to communicatively couple multiple sensing elements. The sections may also include switching elements that may control the communicative couplings between the sensing elements. The sections may further include connection mechanisms (e.g., wiring paths and switching elements) between the sensing elements and one or more common nodes in switching layer 302. For example, as shown in FIG. 3A, section 323 may be configured to communicatively couple to outputs of sensing elements 311, 312, 313, and 314, as shown by the four dashed lines between sensor layer 301 and switching layer 302. In some embodiments, section 323 may be configured to output combined signals gathered from sensing elements 311, 312, 313, and 314 as a common output. In some embodiments, a section (e.g., section 323) may be communicatively coupled to sensing elements (e.g., sensing elements 311, 312, 313, and 314) placed directly above the section. For example, section 323 may have a grid of terminals configured to connect with the outputs of sensing elements 311, 312, 313, and 314. In some embodiments, sections 321, 322, 323, and 324 may be provided in an array structure such that they have a uniform size and shape, and a uniform arrangement. Sections 321, 322, 323, and 324 may be square shaped, for instance. In some embodiments, an isolation area may be provided between adjacent sections to electrically insulate them from one another. In some embodiments, sections may be arranged in an offset pattern, such as a tile layout.

Readout layer 303 may include signal processing circuits for processing outputs of the sensing elements. In some embodiments, signal processing circuits may be provided, which may correspond with each of the sections of switching layer 302. In some embodiments, multiple separate signal processing circuitry sections may be provided, including signal processing circuitry sections 331, 332, 333, and 334. In some embodiments, the signal processing circuitry sections may be provided in an array of sections having a uniform size and shape, and a uniform arrangement. In some embodiments, the signal processing circuitry sections may be configured to connect with an output from corresponding sections of switching layer 302. For example, as shown in FIG. 3A, signal processing circuitry section 333 may be configured to communicatively couple to an output of section 323, as shown by the dashed line between switching layer 302 and readout layer 303. In some embodiments, the signal processing circuitry sections may be configured to constitute corresponding readout channels for corresponding sections of switching layer 302. For example, as shown in FIG. 3A, signal processing circuitry section 333 can constitute a readout channel for section 323 of switching layer.

In some embodiments, readout layer 303 may include input and output terminals. Output(s) of readout layer 303 may be connected to a component for reading and interpreting the output of detector 300A. For example, readout layer 303 may be directly connected to a digital multiplexer, digital logic block, controller, computer, or the like.

The sizes of sections and the number of sensing elements associated with a section may be varied. For example, while FIG. 3A illustrates four sensing elements in one section, embodiments of the disclosure are not so limited.

In some embodiments, arrangements of sensor layer 301, switching layer 302, and readout layer 303 may correspond with one another in a stacked relationship. For example, switching layer 302 may be mounted directly on top of readout layer 303, and sensor layer 301 may be mounted directly on top of switching layer 302. The layers may be stacked such that sections within switching layer 302 are aligned with signal processing circuitry sections (e.g., sections 331, 332, 333, and 334) of readout layer 303. Furthermore, the layers may be stacked such that one or more sensing elements within sensor layer 301 are aligned with a corresponding section in switching layer 302. In some embodiments, sensing elements to be associated with a section may be contained within the section. For example, in a plan view of detector 300A, sensing elements (e.g., sensing elements 311, 312, 313, and 314) of a section (e.g., section 323) may fit within the boundaries of the section. Furthermore, individual sections of switching layer 302 may overlap with corresponding signal processing circuitry sections of readout layer 303. In this manner, predefined areas may be established for associating sensing elements with sections and signal processing circuitry.

FIG. 3B illustrates an exemplary structure of a sensor surface 300B that may form a surface of charged-particle detection device 244, consistent with embodiments of the present disclosure. Sensor surface 300B may be provided with multiple sections of sensing elements, including sections 340, 350, 360, and 370, which are represented by the dashed lines. For example, sensor surface 300B may be the surface of sensor layer 301 in FIG. 3A. Each section may be capable of receiving at least a part of a beam spot emitted from a particular location from wafer 230, such as one of secondary charged-particle beams 236, 238, and 240 as shown in FIG. 2.

Sensor surface 300B may include an array of sensing elements, including sensing elements 315, 316, and 317. In some embodiments, each of sections 340, 350, 360, and 370 may contain one or more sensing elements. For example, section 340 may contain a first plurality of sensing elements, and section 350 may contain a second plurality of sensing elements, and so on. The first plurality of sensing elements and the second plurality of sensing elements may be mutually exclusive. In some embodiments, a sensing element may be a diode or any element similar to a diode that can convert incident energy into a measurable signal. For example, the sensing elements may include a PIN diode, an avalanche diode, an electron multiplier tube (EMT), or other components.

In FIG. 3B, an area 380 may be provided between adjacent sensing elements. Area 380 may be an isolation area to isolate the sides or corners of neighboring sensing elements from one another. In some embodiments, area 380 may include an insulating material that is different from that of the sensing elements of sensor surface 300B. In some embodiments, area 380 may be provided as a square. In some embodiments, area 380 may not be provided between adjacent sides of sensing elements.

In some embodiments, a field programmable detector array may be provided with sensing elements having switching regions integrated between the sensing elements. For example, detectors may be provided such as some of those examples discussed in PCT Application No. PCT/EP2018/074833, filed on Sep. 14, 2018, the content of which is herein incorporated by reference in its entirety. In some embodiments, a switching region may be provided between sensing elements so that some or more of the sensing elements may be grouped when covered by the same charged-particle beam spot. Circuits for controlling the switching regions may be included in the signal processing circuits of the readout layer (e.g., readout layer 303 in FIG. 3A). As used throughout the present disclosure, the expression “a set of sensing elements” shall mean a group of sensing elements of a first quantity. A first set of sensing elements among the set of sensing elements may refer to a subset of sensing elements within the set. A second set of sensing elements may refer to another subset of sensing elements within the set. The first and second sets may or may not be mutually exclusive. A “group” of sensing elements may refer to sensing elements that are associated with one beam spot projected on a detector surface (e.g., within the boundary of the beam spot). First and second sets of sensing elements may refer to different groups of sensing elements that are associated with different beam spots. The sets of sensing elements need not be restricted to particular “sections” of a detector.

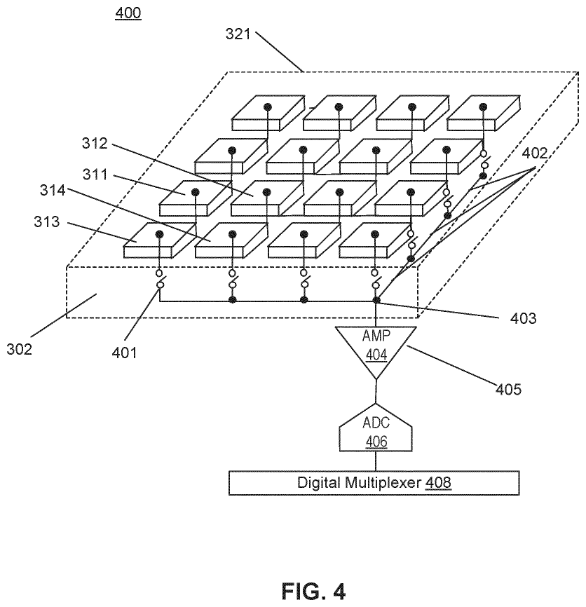

FIG. 4 is a diagram illustrating an exemplary detector array 400 with a switching network consistent with embodiments of the present disclosure. Detector array 400 may be an example embodiment of detector 300A in FIG. 3A. For example, detector array 400 may include a sensor layer (e.g., similar to sensor layer 301 in FIG. 3A), a switching layer (e.g., similar to switching layer 302 in FIG. 3A), and a readout layer (e.g., similar to readout layer 303 in FIG. 3A). The sensor layer of detector array 400 may include multiple sensing elements, including sensing elements 311, 312, 313, and 314. In some embodiments, each of the sensing elements of detector array 400 may have a uniform size, shape, and arrangement. The sensing elements of detector array 400 may generate an electric current signal commensurate with the charged particles (e.g., exiting electrons) received in the active areas of the sensing elements. The “active areas” herein may refer to areas of the sensing elements having radiation sensitivity above a predetermined threshold value.

The switching layer 302 of detector array 400 may include one or more wiring paths 402. Wiring paths 402 may be configured to communicatively couple the sensing elements of detector array 400. As shown in FIG. 4, detector array 400 includes a section 321 having 4×4 sensing elements, including sensing elements 311, 312, 313, and 314. In FIG. 4, switching layer 402 of detector array 400 may include inter-element switching elements (not shown) between any two adjacent sensing elements. Switching layer 302 of detector array 400 may also include inter-element switching elements communicatively coupled to edges of neighboring sensing elements. Wiring paths 402 may be configured to communicatively couple to outputs of sensing elements (e.g., sensing elements 311, 312, 313, and 314) in section 321. For example, wiring paths 402 may have a grid of terminals (shown as round black dots at the centers of the sensing elements) configured to connect with the outputs of sensing elements 311, 312, 313, and 314. In some embodiments, wiring paths 402 may be provided in switching layer 302 of detector array 400. In FIG. 4, wiring paths 402 are communicatively coupled to the above sensing elements (e.g., sensing elements 311, 312, 313, and 314). In some embodiments, wiring paths 402 may include lines of conductive material printed on the base substrate, flexible wires, bonding wires, or the like. While it is illustrated in FIG. 4 that section 321 has 4×4 sensing elements, it will be appreciated that FIG. 4 is provided as an example and the present disclosure is applicable to a detector array having section(s) with any number of sensing elements.

In FIG. 4, switching elements 401 may be provided between the outputs of the sensing elements and wiring paths 402. In some embodiments, switching elements 401 may be provided in switching layer 402 of detector array 400. In some embodiments, each sensing element (e.g., sensing element 313) is provided with its corresponding switching element 401 that is configured to communicatively couple the output of the sensing element to a common node 403 for a section (e.g., section 321) comprising the sensing element. In some embodiments, outputs of sensing elements in one section can be provided to its readout channel 404 common for sensing elements of the section via common node 403. In some embodiments, switching elements 401 may be provided so that outputs of individual sensing elements can be connected or disconnected with a common output (e.g., at common node 403) of section 321. In some embodiments, switching layer 302 of detector array 400 may further include corresponding circuits for controlling the switching elements. In some embodiments, switching elements may be provided in a separate switch-element matrix that may itself contain circuits for controlling the switching elements.

The readout layer of detector array 400 may include signal conditioning circuits for processing outputs of the sensing elements. In some embodiments, the signal conditioning circuits may convert the generated current signal into a voltage that may represent the intensity of a received beam spot, or may amplify the generated current signal into an amplified current signal. The signal conditioning circuit may include, for example, an amplifier 404 and one or more analog switching elements (not shown in FIG. 4). The amplifier 404 may be a high speed transimpedance amplifier, a current amplifier, or the like. In FIG. 4, amplifier 404 may be communicatively coupled to the common output of section 321 for amplifying the output signals of the sensing elements of section 321. In some embodiments, amplifier 404 may be a single-stage or a multi-stage amplifier. For example, if amplifier 404 is a multi-stage amplifier, it may include a pre-amplifier and a post-amplifier, or include a front-end stage and a post stage, or the like. In some embodiments, amplifier 404 may be a variable gain amplifier, such as a variable gain transimpedance amplifier (VGTIA), a variable gain charge transfer amplifier (VGCTA), or the like. The conditioning circuit may be coupled to a signal path that may include, for example, an analog-to-digital converter (ADC) 406. In FIG. 4, ADC 406 may be communicatively coupled to the output of the conditioning circuit (e.g., including amplifier 404) to convert the analog output signals of the sensing elements of section 321 to digital signals. The readout layer of detector array 400 may also include other circuits for other functions. For example, the readout layer of detector array 400 may include switch-element actuating circuits that may control the switching elements in the switching layer. For ease of explanation without causing ambiguity, the signal path between the sensing elements and ADC 406 may be referred to as an “analog signal path,” constituting a readout channel 405 for the sensing elements. For example, the analog signal path in FIG. 4 includes the above-described signal conditioning circuit (e.g., including amplifier 404). The input of the analog signal path is communicatively coupled to the sensing elements, and the output of the analog signal path is communicatively coupled to ADC 406.

In some embodiments, ADC 406 may include output terminals communicatively coupled to a component (e.g., a component inside or outside the readout layer of detector array 400) for reading and interpreting the digital signal converted by ADC 406. In FIG. 4, ADC 406 is communicatively coupled to a digital multiplexer 408. In some embodiments, digital multiplexer 408 may be arranged in the readout layer of detector array 400. Digital multiplexer 408 may receive multiple input signals and convert them as an output signal. The output signal of digital multiplexer 408 may be converted back to the multiple input signals. The output signal of digital multiplexer 408 may be further transmitted to a data processing stage (e.g., image processing system 290 in FIG. 2).

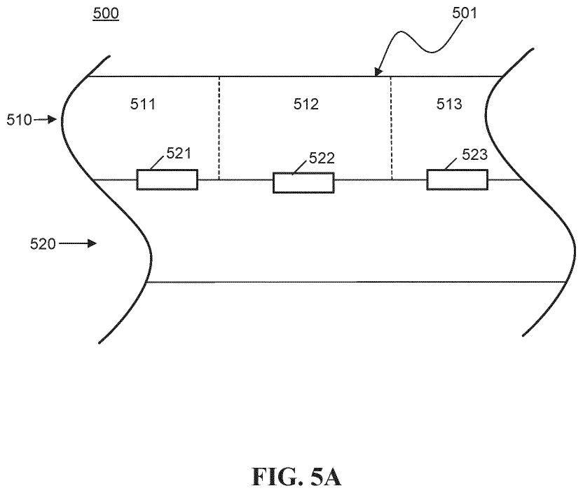

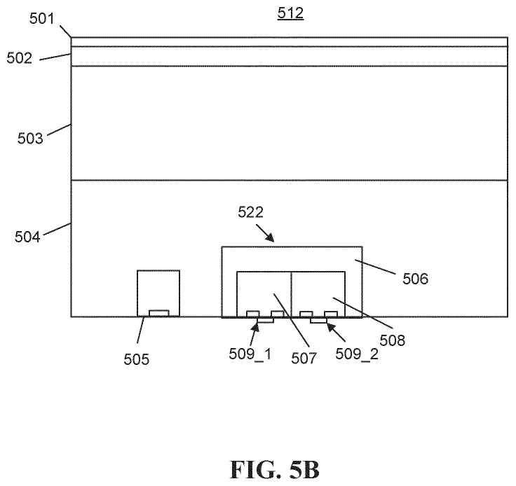

FIG. 5A is a diagram illustrating a cross-sectional view of a detector structure, consistent with embodiments of the present disclosure. Detector 500 may be provided as charged-particle detection device 244 in a charged-particle beam tool 104 as shown in FIG. 2. Detector 500 may be configured to have multiple layers stacked in a thickness direction, the thickness direction being substantially parallel to an incidence direction of a charged-particle beam. In some embodiments, detector 500 may be provided such as some of those examples discussed in PCT Application No. PCT/EP2018/074833, filed on Sep. 14, 2018, the content of which is herein incorporated by reference in its entirety.

In FIG. 5A, detector 500 may include a sensor layer 510 and a circuit layer 520. In some embodiments, sensor layer 510 may represent sensor layer 301 in FIG. 3A, and circuit layer 520 may represent readout layer 303 in FIG. 3A. In some embodiments, circuit layer 520 may include a processing system. Circuit layer 520 may also be configured to receive the output current detected in sensor layer 510 via a switching network including switching elements 521, 522, or 523. In some embodiments, a switching layer can be incorporated into sensor layer 510 or circuit layer 520. In some embodiments, detector 500 can include additional layer for a switching network between sensor layer 510 and circuit layer 520. For example, sensor layer 510 may represent sensor layer 301 and switching 302 in FIG. 3A, and circuit layer 520 may represent readout layer 303 in FIG. 3A. In some embodiments, detector 500 may include additional layers in addition to sensor layer 301, switching layer 302, and readout layer 303.

In some embodiments, sensor layer 510 may be provided with a sensor surface 501 for receiving incident charged particles. Sensing elements, including sensing elements 511, 512, and 513 (differentiated by dashed lines), may be provided in sensor layer 510. For example, sensor surface 501 may be similar to sensor surface 300B in FIG. 3B. In some embodiments, sensing elements 511, 512, and 513 may be among the sensing elements (e.g., sensing elements 311, 312, 313, and 314) of detector array 400 in FIG. 4. As shown in FIG. 5A, switching elements, including switching elements 521, 522, and 523, may be provided for each sensing element. Switching elements 521, 522, and 523 may be embedded in sensor layer 510. In some embodiments, switching elements 521, 522, and 523 may be among the switching elements 401 of detector array 400 in FIG. 4. In some embodiments, sensor layer 510 or circuit layer 520 may include interconnects (e.g., metal lines), and various electronic circuit components. In some embodiments, sensor layer 510 can further includes switching elements that connect adjacent sensing elements.

In some embodiments, sensing elements 511, 512, and 513 may be separated by an isolation area (indicated by the dashed lines) extending in the thickness direction. For example, sides of sensing elements 511, 512, and 513 that are parallel to the thickness direction may be isolated from each other by the isolation areas (e.g., area 380 in FIG. 3B).

In some embodiments, sensor layer 510 may be configured as one or more diodes where sensing elements 511, 512, and 513 are similar to sensing elements 315, 316, and 317 of FIG. 3B. Switching elements 521, 522, and 523 may be configured as transistors (e.g., MOSFETs). Each of sensing elements 511, 512, 513 may include outputs for making electrical connections to circuit layer 520. For example, the outputs may be integrated with switching elements 521, 522, and 523, or may be provided separately. In some embodiments, the outputs may be integrated in a bottom layer of sensor layer 510 (e.g., a metal layer).

Although FIG. 5A depicts sensing elements 511, 512, and 513 as discrete units when viewed in cross-section, such divisions may not actually be physical. For example, the sensing elements of detector 500 may be formed by a semiconductor device constituting a PIN diode device that can be manufactured as a substrate with multiple layers including a P-type region, an intrinsic region, and an N-type region. In such an example, sensing elements 511, 512, 513 may be contiguous in cross-sectional view. In some embodiments, the switching elements (e.g., switching elements 521, 522, and 523) may be integrated with the sensing elements. While detector 500 is illustrated to be implemented as a monolithic layer referring to FIG. 5A, it will be appreciated that descriptions of detector 500 that are not limited to a monolithic structure can also be applicable to other types of detector structures, e.g., having a two-die configuration. In some embodiments, switching elements may be integrated within the sensor layer, integrated within other layers, or may be provided partially or fully in existing layers. In some embodiments, for example, the sensor layer may contain wells, trenches, or other structures, wherein the switching elements are formed in those structures.

FIG. 5B is a diagram illustrating a cross-sectional view of sensing element 512 of detector 500, consistent with embodiments of the present disclosure. FIG. 5B illustrates sensing element 512 into which switching element 522 is incorporated as an example. In FIG. 5B, sensing element 512 may include a P-well and an N-well for forming switching elements and other active or passive elements that may be communicatively coupled to other components of sensor layer 510 or circuit layer 520. Although FIG. 5B only shows one full sensing element 512, it is understood that sensor layer 510 may be made up of multiple sensing elements similar to sensing element 512 (e.g., sensing elements 511 and 513), which may be contiguous in cross-sectional view.

In some embodiments, sensing element 512 may include a diode device having a surface layer 501, a P-type region 502, a P-epitaxial region 503, an N-type region 504, and other components. Surface layer 501 may form a detection surface (e.g., an active area) of a detector that receives incident charged particles. For example, surface layer 501 may be a metal layer (e.g., formed by aluminum or other conductive materials). On an opposite side from surface layer 501, there may be provided an electrode 505 as a charge collector. Electrode 505 may be configured to output a current signal representing the number of charged particles received in the active area of sensing element 512.

In some embodiments, switching element 522 may be formed by metal oxide semiconductor (MOS) devices. For example, multiple MOS devices may be formed in a back side of N-type region 504 in FIG. 5B, and the back side of N-type region 504 may be in contact with sensor layer 510 in FIG. 5A. In some embodiments, a MOS device can include various types of MOS devices including PMOS devices, NMOS devices, or CMOS devices. As an example of a MOS device, there may be provided a deep P-well 506, an N-well 507, and a P-well 508. A PMOS (P-channel MOS) transistor 509_1 and an NMOS (N-channel MOS) transistor 509_2 can be formed. In some embodiments, PMOS transistor 509_1 and NMOS transistor 509_2 can form a CMOS (complementary MOS) transistor. In some embodiments, the MOS devices may be fabricated by etching, patterning, and other processes and techniques. It will be understood that various other devices may be used, such as bipolar semiconductor devices, etc., and devices may be fabricated by various processes.

In operation of sensing element 512, when charged particles (e.g., secondary charged-particle beams 236, 238, and 240 in FIG. 2) impinge on surface layer 501, the body of sensing element 512, including, e.g., a depletion region, may be flooded with charge carriers generated from the impinged charged particles. Such a depletion region may extend through at least a portion of the volume of the sensing element. For example, the charged particles may be electrons, and the impinged electrons may create and energize electron-hole pairs in a depletion region of the sensing element. The energized electrons among the electron-hole pairs may have further energy such that they may also generate new electron-hole pairs. Electrons generated from the impinged charged particles may contribute to signal generated in each sensing element.

With reference to FIG. 5B, a depletion region in sensing element 512 may include an electric field between P-type region 502 and N-type region 504, and the electrons and the holes may be attracted by P-type region 502 and N-type region 504, respectively. When the electrons reach P-type region 502 or when the holes reach N-type region 504, a detection signal may be generated. Thus, sensing element 512 may generate an output signal, such as current, when a charged particle beam is incident on sensing element 512. Multiple sensing elements may be connected, and a group of sensing elements may be used to detect intensity of a charged particle beam spot. When a charged particle beam spot covers multiple adjacent sensing elements (e.g., sensing elements 511, 512, and 513), the sensing elements may be grouped together (“merged”) for collecting current. For example, outputs of the sensing elements may be merged by turning on switching elements (e.g., switching elements 519 and 521) corresponding to the sensing elements. Signals from sensing elements in a group may be collected and sent to a signal conditioning circuit connected to the group. The number of sensing elements in a group may be an arbitrary number related to the size and shape of the beam spot. The number may be 1 or greater than 1.

In some embodiments, a detector may be configured so that individual sensing elements may communicate with external components via, for example, signal or data lines and address signals. A detector may be configured to control switching elements so that output current or voltage of two or more sensing elements can be combined. Thus, when sensing element 512 is activated, all of the area under surface layer 601 may become active.

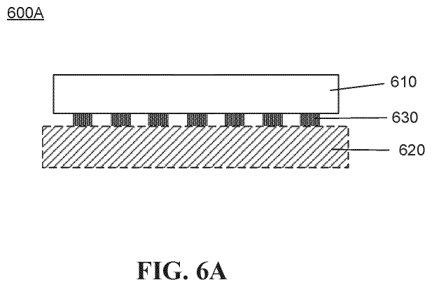

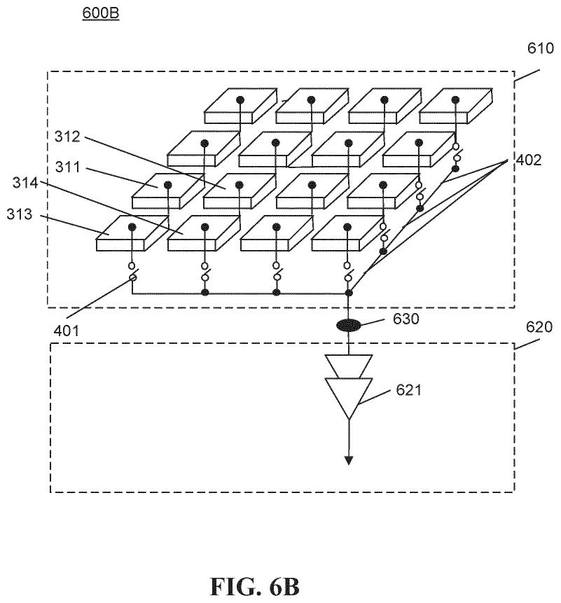

FIG. 6A is a diagram illustrating a cross-sectional view of a two-die detector configuration, consistent with embodiments of the present disclosure. In some embodiments, a detector can be formed by boding together two separate chips, one including sensing elements and another including circuitry. As shown in FIG. 6A, detector 600A can include a first chip 610 and a second chip 620. Each chip can be formed on its own semiconductor substrate, which is thin. In some embodiments, first chip 610 and second chip 620 can be connected via chip-to-chip connections 630. In some embodiments, first chip 610 and second chip 620 can be connected via solder bumps as chip-to-chip connection 630. In some embodiments, first chip 610 and second chip 620 can be connected via direct bonding as chip-to-chip connection 630. As first chip 610 includes sensing elements such as diodes, first chip 610 can be called the diode chip in this disclosure. As second chip 620 includes readout integrated circuit (ROIC) formed therein, second chip 620 can be called the ROIC chip in this disclosure. In some embodiments, the readout integrated circuit can include signal conditioning circuits for processing outputs of the sensing elements.

Making connections between the separate chips may introduce complications, such as the need to accurately align and reliably bond all connections between the chips. Furthermore, loss may be incurred at various junctions such as chip-to-chip connections between the chips. Loss may lead to a reduction in signal-to-noise ratio (SNR). Further, chip-to-chip connections such as solder bumps can come with substantial parasitic components, e.g., for electrostatic discharge (ESD) protection circuitry. Therefore, reducing the number of chip-to-chip connections to be included in detector 600A can be beneficial in terms of introducing less complications as well as less parasitic components.

According to some embodiments of the present disclosure, a switching network can be formed in first chip 610 along with sensing elements as shown in FIG. 6B, which illustrates an exemplary detector architecture 600B. In FIG. 6B, first chip 610 can include a switching network comprising switching elements 401 in addition to sensing elements. Second chip 620 can include readout channels 621. As illustrated referring to FIG. 4, a switching network is configured to connect outputs of grouped sensing elements to one readout channel. Similarly, FIG. 6B illustrates a group of sensing elements (e.g., sensing elements 311, 312, 313, and 314) that share one readout channel (e.g., readout channel 621). As shown in FIG. 6B, outputs of the grouped sensing elements are combined by a switching network including switching elements 401, and the combined outputs are provided to the corresponding readout channel 621 via a common chip-to-chip connection 630.

Thereby, according to detector architecture 600B of FIG. 6B, the number of chip-to-chip connections between the first chip 610 and second chip 620 can be reduced, which in turn may reduce complications introduced by the chip-to-chip connections. According to detector architecture 600B of FIG. 6B, parasitic resistance or capacitance introduced to the detector can be reduced as the number of chip-to-chip connections decreases. Accordingly, performance of a detector can be improved as the parasitic resistance or capacitance has a negative impact on detector's bandwidth, which is one of the factors that determines a detector's performance. A bandwidth of a detector relates to an operating speed of the detector and can indicate how quickly the detector responds to incident electrons, e.g., including receiving electrons, generating currents commensurate with the received electrons, transmitting the generated currents to a readout circuit to detect or measure the currents. Because parasitic resistance or capacitance causes RC delay of a detector and therefore slows down an operating speed of the detector, a bandwidth of the detector can be deteriorated when there is parasitic resistance or capacitance. Further, parasitic resistance or capacitance can further be suppressed as a wiring path between the sensing elements and switching elements can be shortened in detector architecture 600B of FIG. 6B.

As the technology advances, the chip sizes are smaller while the number of sensing elements mounted on the chip increases. Therefore, reducing the number of chip-to-chip connections between the first chip and the second chip becomes more beneficial. For example, a typical chip has 10 mm by 10 mm size, and at least 1000 PIN diodes are integrated on to the chip. However, some chip-to-chip connection technique (e.g., solder bumps) requires an interconnection pitch of about 100 μm, which results in limiting the number of chip-to-chip connections that can be implemented in a small chip of a detector. While FIG. 6B illustrates only a group of sensing elements that share one readout channel 621, it will be appreciated that detector 600B can include multiple groups of sensing elements and second chip 620 include multiple readout channels 621 each receiving outputs from its corresponding group.

As discussed with respect to FIG. 5B, during operation of a charged particle beam inspection apparatus, a primary electron beam may be projected onto a sample, and secondary particles including secondary electrons or backscattered electrons may be directed from the sample to sensing element 512. Sensing element 512 may be configured so that an incoming electron generates carriers including electron-hole pairs in P-epitaxial region 503. Numerous electron-hole pairs may be generated due to a mechanism triggered by the arrival of an incoming electron, such as impact ionization. During such interaction between electrons and sensing element 512, X-rays are generated. Inventors have discovered that such X-rays may damage switching elements of a detector.

While recent studies have found that the switching elements of the detector tend to get damaged after e-beam exposure for a certain period of time, and such damages shorten the lifetime of the detector and deteriorate the overall throughput of the SEM tool, root causes thereof have not been discovered. Because the SEM tool is not operated in generally known X-ray radiation environments such as space, military use, or nuclear environment, nobody has anticipated that X-ray exposure could cause damage to the switching elements. Moreover, the detector usually does not include electronic circuitry in proximity to the sensing elements, damages to the detector caused by X-ray exposure hasn't been a serious issue. However, as illustrated referring to FIGS. 4, 5A, 5B, and 6B, detectors of a SEM tool can be formed to include switching elements close to sensing elements, and these switching elements may be damaged by X-ray exposure, thereby seriously impacting performance of the detectors and the SEM tool itself.

Further, X-ray exposure to switching elements such as transistors (e.g., MOS transistors) can also increase the resistance of the transistors in the on state, resulting in a reduced operating speed of the detector and thus reducing the bandwidth of the detector. Thereby, the overall throughput of the SEM tool can be deteriorated. When the transistor is shut off, it is ideal that no current passes through the transistor. In reality, even when the transistor is turned off, current leakage can happen. When the transistor is exposed to X-rays, the threshold current leakage increases while the transistor is in the off state. Such threshold current leakage can cause errors in generating SEM images because pixels are not isolated due to the threshold current leakage. For example, when acquiring a SEM image, a shadow image or a neighboring image may occur due to the threshold current leakage from the shut off transistors that are coupled to corresponding pixelated sensing elements.

As discussed above, many sensing elements are crammed on a small chip. Switching elements are also integrated with the sensing elements on the same chip according to some embodiments of the present disclosure. For example, a typical chip has 10 mm by 10 mm size, and at least 1000 PIN diodes are integrated on to the chip. Therefore, it is hard to maintain a sufficient distance between switching elements and sensing elements that are a source of X-rays such that damage to switching elements caused by X-ray exposure can be suppressed.

According to some embodiments of the present disclosure, radiation hardened design techniques can be used in the detector in which switching elements are positioned in proximity to sensing elements. For example, in detector architectures shown in FIGS. 5A or 6B, radiation hardened design techniques can be used. In some embodiments, a detector (e.g., detector architecture of FIG. 5A or FIG. 6B) can be formed to include switching elements using only a radiation tolerant device such as PMOS transistors, or bi-polar transistors. For example, a switching element (e.g., switching element 522 of FIG. 5B) of a detector can be formed without using NMOS transistors (e.g., NMOS transistor 509_2 of FIG. 5B) but using PMOS transistors (e.g., PMOS transistor 509_1) or bi-polar transistors. In some embodiments, a detector can be formed using an NMOS transistor having a radiation hardened design. For example, a switching element (e.g., switching element 522 of FIG. 5B) of a detector can be formed to include an NMOS transistor having a radiation hardened design, e.g., for replacing NMOS transistor 509_2 in FIG. 5B.

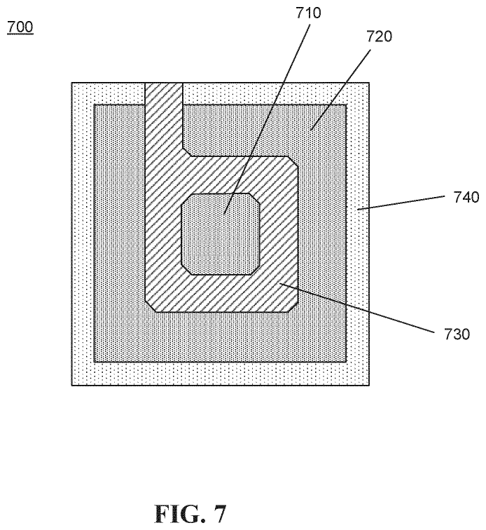

FIG. 7 is a diagram illustrating a top view of an example radiation hardened NMOS transistor, consistent with embodiments of the present disclosure. As shown in FIG. 7, a radiation hardened NMOS transistor 700 can have a gate enclosed layout. Radiation hardened NMOS transistor 700 can have a first N-type source/drain diffusion region 710, a second N-type source/drain region 720, and a gate 730 enclosing one of first and second N-type source/drain diffusion regions 710 and 720. Radiation hardened NMOS transistor 700 can be formed in a P-type well 740. The enclosed layout of radiation hardened NMOS transistor 700 can prevent the leakage current between the source and the drain through oxides from being generated due to X-ray exposure. While the enclosed layout of the radiation hardened NMOS transistor has been illustrated as a radiation hardened NMOS transistor configuration, it will be appreciated that other radiation hardened designs or techniques can also be applicable.

As discussed above, radiation induced damages to the detector of the SEM, and to the SEM can be ameliorated by using radiation hardened devices only for switching elements of the detector. However, the detector using radiation hardened devices can still be susceptible to X-ray exposure when the radiation energy is high or the exposure time is long. For example, even the PMOS transistor that is more durable against X-rays than the NMOS transistor can also be damaged if the PMOS transistor is exposed to X-rays having high energy or exposed to X-rays over longer time frames. Moreover, radiation hardened NMOS transistors add additional parasitic components, which can degrade detector/SEM performance. Therefore, according to some embodiments of the present disclosure, a detector architecture having switching elements in the ROIC chip (e.g., second chip 620) instead of the diode chip (e.g., first chip 610).

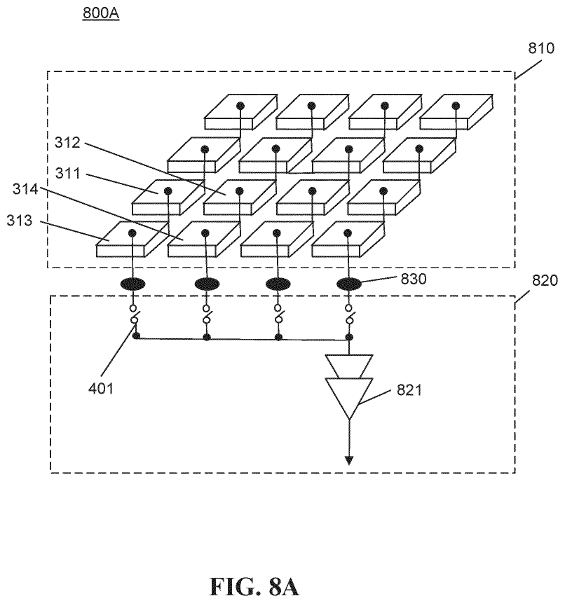

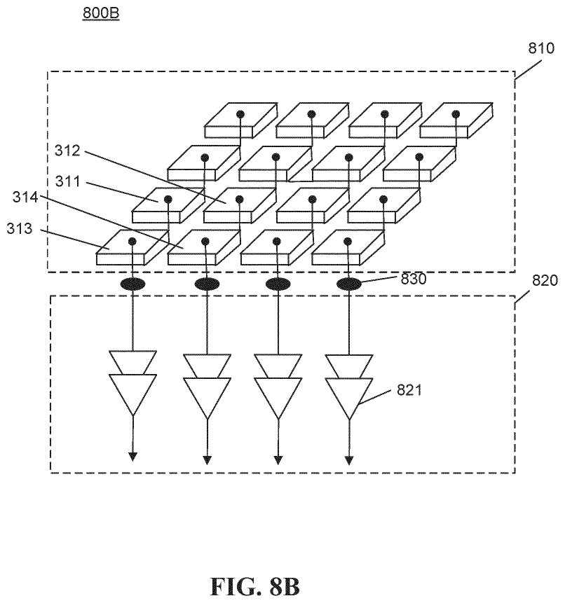

FIG. 8A is a diagram illustrating an exemplary detector architecture, consistent with embodiments of the present disclosure. As shown in FIG. 8A, detector 800A can be configured as a two-die configuration including a first chip 810 and a second chip 820. First chip 810 can include sensing elements 311, 312, 313, and 314. Second chip 820 includes a switching network, which comprising switching elements 401, and a readout integrated circuit including a readout channel 821. In some embodiments, the readout integrated circuit can be formed to include the switching network including switching elements. As shown in FIG. 8A, outputs of the grouped sensing elements are combined by a switching network including switching elements 401, and the combined outputs are provided to the corresponding readout channel 821. Here, as the switching network comprising switching elements 401 are integrated with readout channel 821, each output of sensing elements is provided to an input terminal of a corresponding switching element 401 via chip-to-chip connections 830. Therefore, detector 800A of FIG. 8A can be configured to have the same number of chip-to-chip connections 830 as the sensing elements.

While FIG. 8A illustrates connections between sensing elements and switching elements of the first row for clarity, it will be noted that such connections can be formed for all sensing elements in FIG. 8A. Further, while FIG. 8A illustrates only a group of sensing elements that share one readout channel 821, it will be appreciated that detector 800A can include multiple groups of sensing elements and second chip 820 can include multiple readout channels 821, each receiving outputs from its corresponding group of sensing elements.

Because chip-to-chip connections 830 require a certain interconnection pitch therebetween, the number of chip-to-chip connections 830 that can be formed in a certain chip area may be limited. As the technology advances, the interconnection pitch that is required for chip-to-chip connections may decrease. For example, an interconnection pitch of direct bonding chip-to-chip connections is much smaller (e.g., up to single digit μm level) than that of solder bump chip-to-chip connections. Therefore, according to detector architecture shown in FIG. 8A, radiation damages to switching elements, a detector, and a SEM tool may further be ameliorated without causing serious restrictions on the number of sensing elements to be included in a SEM detector.

According to a detector architecture shown in FIG. 8A, radiation induced damages to the detector of the SEM tool, and to the SEM tool can be significantly reduced as switching elements are positioned on a different chip (e.g., ROIC chip) from X-ray radiation source, i.e., sensing elements. However, X-rays can still reach switching elements and thus affect the performance of the SEM detector and the SEM tool itself in the long term. Moreover, as the technology advances, the distance between the two separate chips (i.e., sensing element chip and ROIC chip) can become shorter. Some embodiments of the present disclosure provide a detector architecture without switching elements. FIG. 8B is a diagram illustrating another exemplary detector architecture, consistent with embodiments of the present disclosure. In this embodiment, similar to one shown in FIG. 8A, detector 800B can be configured as a two-die configuration including a first chip 810 and a second chip 820. First chip 810 includes sensing elements 311, 312, 313, and 314, and second chip 820 includes readout channels (e.g., readout channel 821). Here, because detector 800B is formed without having switching elements, multiple outputs of multiple sensing elements are connected to their corresponding readout channels 821 via chip-to-chip connections (e.g., chip-to-chip connection 830). For example, each output of sensing elements is provided to an input terminal of corresponding readout channel 821 via chip-to-chip connections 830. Therefore, detector 800B of FIG. 8B can be configured to have the same number of chip-to-chip connections 830 as the sensing elements. Such a detector architecture without switching elements can still be useful for multi-beam inspection system depending on the concentration within a single e-beam SEM tool or a pitch between different e-beams. Because a detector architecture shown in FIG. 8B does not include switching elements that are damaged by X-ray exposure, X-ray induced damages to detector 800B and a SEM tool can be avoided. While FIG. 8B illustrates connections between sensing elements and switching elements of the first row for clarity, it will be noted that such connections can be formed for all sensing elements in FIG. 8B.

The embodiments may further be described using the following clauses:
1. A detector for a scanning electron microscope (SEM) system, comprising:
a semiconductor substrate; and
a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.
2. The detector of clause 1, further comprising a plurality of sensing elements formed on the semiconductor substrate.
3. The detector of clause 2, wherein the switching network has a plurality of input terminals connecting to a different sensing element of the plurality of sensing elements.
4. The detector of clause 2 or 3, wherein the switching network has a common node communicatively coupled with a group of sensing elements among the plurality of sensing elements and configured to connect, via a chip-to-chip connection, to a read-out channel of a readout substrate.
5. The detector of clause 4, wherein each sensing element of the plurality of sensing elements is configured to generate an electrical signal in response to electrons incident on the each sensing element, and the switching network is configured to combine electrical signals generated from the group of sensing elements and to transmit the combined electrical signals to the read-out channel via the common node.
6. The detector of clause 2 or 3, wherein the switching network is configured to transmit an electrical signal from each group of multiple groups of the plurality of sensing elements, via a chip-to-chip connection, to a corresponding read-out channel of a readout substrate having multiple read-out channels corresponding to the multiple groups.
7. The detector of clause 6, wherein each group of the multiple groups is associated with a different secondary electron beam of a plurality of secondary electron beams of the SEM system.
8. The detector of any one of clauses 2-7, wherein the plurality of sensing elements include at least 1000 PIN diodes.
9. A detector for a scanning electron microscope (SEM) system, comprising:
a semiconductor substrate;
a plurality of transistors formed on the semiconductor substrate and configured to form a switching network, the switching network having a plurality of input terminals each configured to connect, via a chip-to-chip connection, to a different sensing element of a plurality of sensing elements of another substrate, and the switching network having a common node communicatively coupled with a group of sensing elements among the plurality of sensing elements; and
read-out circuitry formed on the semiconductor substrate and comprising a read-out channel communicatively coupled to the common node.
10. The detector of clause 9, wherein each sensing element of the plurality of sensing elements is configured to generate an electrical signal in response to particles incident on the each sensing element, and the switching network is configured to combine electrical signals generated from the group of sensing elements and to transmit the combined electrical signals to the read-out channel via the common node.
11. The detector of clause 10, wherein the switching network is configured to transmit an electrical signal from each group of multiple groups of the plurality of sensing elements to a corresponding read-out channel of the readout circuitry having multiple read-out channels corresponding to the multiple groups.
12. The detector of clause 11, wherein each group of the multiple groups is associated with a different secondary electron beam of a plurality of secondary electron beams of the SEM system.
13. The detector of any one of clauses 9-12, wherein the plurality of sensing elements include at least 1000 PIN diodes.
14. A detector for a scanning electron microscope (SEM) system, comprising:
a first semiconductor substrate;
a plurality of sensing elements formed on the first semiconductor substrate;
a second semiconductor substrate; and read-out circuitry formed on the second semiconductor substrate and comprising a plurality of readout channels each corresponding to a different sensing element of the plurality of sensing elements and configured to receive an electric signal from a corresponding sensing element via a chip-to-chip connection.
15. The detector of clause 14, wherein each sensing element of the plurality of the sensing elements are configured to connect, via a chip-to-chip connection, to a corresponding readout channel.
16. The detector of clause 14, wherein each sensing element of the plurality of sensing elements is configured to generate an electrical signal in response to electrons incident on the each sensing element.
17. The detector of any one of clauses 14-16, wherein the plurality of sensing elements include at least 1000 PIN diodes.
18. A readout integrated circuit for a scanning electron microscope (SEM) system, comprising:
a semiconductor substrate; and
a plurality of transistors formed on the semiconductor substrate and configured to form a switching network, the switching network having a plurality of input terminals each configured to connect, via a chip-to-chip connection, to a different sensing element of a plurality of sensing elements of another substrate, and the switching network having a common node communicatively coupled with a group of sensing elements among the plurality of sensing elements.
19. The readout integrated circuit of clause 18, further comprising a readout channel formed on the semiconductor substrate,
wherein each sensing element of the plurality of sensing elements is configured to generate an electrical signal in response to particles incident on the each sensing element, and the switching network is configured to combine electrical signals generated from the group of sensing elements and to transmit the combined electrical signals to the read-out channel via the common node.
20. The readout integrated circuit of clause 18, further comprising multiple readout channels corresponding to the multiple groups,
wherein the switching network is configured to transmit an electrical signal from each group of multiple groups of the plurality of sensing elements to a corresponding readout channel among the multiple read-out channels.
21. The readout integrated circuit of clause 20, wherein each group of the multiple groups is associated with a different secondary electron beam of a plurality of secondary electron beams of the SEM system.
22. The readout integrated circuit of any one of clauses 18-21, wherein the plurality of sensing elements include at least 1000 PIN diodes.
23. A charged-particle inspection system comprising:
a charged-particle beam source configured to generate a primary charged-particle beam for sample scanning; and
a detector configured to receive a secondary charged-particle beam exiting a sample from a point of incidence of the primary charged-particle beam at the sample, the detector comprising:
a semiconductor substrate; and
a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.
24. The charged-particle inspection system of clause 23, wherein the detector further comprises a plurality of sensing elements formed on the semiconductor substrate.
25. The charged-particle inspection system of clause 24, wherein the switching network has a plurality of input terminals connecting to a different sensing element of the plurality of sensing elements.
26. The charged-particle inspection system of clause 24 or 25, wherein the switching network has a common node communicatively coupled with a group of sensing elements among the plurality of sensing elements and configured to connect, via a chip-to-chip connection, to a read-out channel of a readout substrate.
27. The charged-particle inspection system of clause 26, wherein each sensing element of the plurality of sensing elements is configured to generate an electrical signal in response to electrons incident on the each sensing element, and the switching network is configured to combine electrical signals generated from the group of sensing elements and to transmit the combined electrical signals to the read-out channel via the common node.
28. The charged-particle inspection system of clause 24 or 25, wherein the switching network is configured to transmit an electrical signal from each group of multiple groups of the plurality of sensing elements, via a chip-to-chip connection, to a corresponding read-out channel of a readout substrate having multiple read-out channels corresponding to the multiple groups.
29. The charged-particle inspection system of clause 28, wherein each group of the multiple groups is associated with a different secondary electron beam of a plurality of secondary electron beams of the SEM system.
30. The charged-particle inspection system of any one of clauses 24-29, wherein the plurality of sensing elements include at least 1000 PIN diodes.
31. A charged-particle inspection system comprising:
a charged-particle beam source configured to generate a primary charged-particle beam for sample scanning; and
a detector configured to receive a secondary charged-particle beam exiting a sample from a point of incidence of the primary charged-particle beam at the sample, the detector comprising:
a semiconductor substrate;
a plurality of transistors formed on the semiconductor substrate and configured to form a switching network, the switching network having a plurality of input terminals each configured to connect, via a chip-to-chip connection, to a different sensing element of a plurality of sensing elements of another substrate, and the switching network having a common node communicatively coupled with a group of sensing elements among the plurality of sensing elements; and
read-out circuitry formed on the semiconductor substrate and comprising a read-out channel communicatively coupled to the common node.
32. The charged-particle inspection system of clause 31, wherein each sensing element of the plurality of sensing elements is configured to generate an electrical signal in response to particles incident on the each sensing element, and the switching network is configured to combine electrical signals generated from the group of sensing elements and to transmit the combined electrical signals to the read-out channel via the common node.
33. The charged-particle inspection system of clause 32, wherein the switching network is configured to transmit an electrical signal from each group of multiple groups of the plurality of sensing elements to a corresponding read-out channel of the readout circuitry having multiple read-out channels corresponding to the multiple groups.
34. The charged-particle inspection system of clause 33, wherein each group of the multiple groups is associated with a different secondary electron beam of a plurality of secondary electron beams of the SEM system.
35. The charged-particle inspection system of any one of clauses 31-34, wherein the plurality of sensing elements include at least 1000 PIN diodes.
36. A charged-particle inspection system comprising:
a charged-particle beam source configured to generate a primary charged-particle beam for sample scanning; and
a detector configured to receive a secondary charged-particle beam exiting a sample from a point of incidence of the primary charged-particle beam at the sample, the detector comprising:
a first semiconductor substrate;
a plurality of sensing elements formed on the first semiconductor substrate;
a second semiconductor substrate; and
read-out circuitry formed on the second semiconductor substrate and comprising a plurality of readout channels each corresponding to a different sensing element of the plurality of sensing elements and configured to receive an electric signal from a corresponding sensing element via a chip-to-chip connection.
37. The charged-particle inspection system of clause 36, wherein each sensing element of the plurality of the sensing elements are configured to connect, via a chip-to-chip connection, to a corresponding readout channel.
38. The charged-particle inspection system of clause 36, wherein each sensing element of the plurality of sensing elements is configured to generate an electrical signal in response to electrons incident on the each sensing element.
39. The charged-particle inspection system of any one of clauses 36-38, wherein the plurality of sensing elements include at least 1000 PIN diodes.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A detector for a scanning electron microscope (SEM) system, comprising:
a semiconductor substrate; and
a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.

2. The detector of claim 1, further comprising a plurality of sensing elements formed on the semiconductor substrate.

3. The detector of claim 2, wherein the switching network has a plurality of input terminals connecting to a different sensing element of the plurality of sensing elements.

4. The detector of claim 2, wherein the switching network has a common node communicatively coupled with a group of sensing elements among the plurality of sensing elements and configured to connect, via a chip-to-chip connection, to a read-out channel of a readout substrate.

5. The detector of claim 4, wherein each sensing element of the plurality of sensing elements is configured to generate an electrical signal in response to electrons incident on the each sensing element, and the switching network is configured to combine electrical signals generated from the group of sensing elements and to transmit the combined electrical signals to the read-out channel via the common node.

6. The detector of claim 2, wherein the switching network is configured to transmit an electrical signal from each group of multiple groups of the plurality of sensing elements, via a chip-to-chip connection, to a corresponding read-out channel of a readout substrate having multiple read-out channels corresponding to the multiple groups.

7. The detector of claim 6, wherein each group of the multiple groups is associated with a different secondary electron beam of a plurality of secondary electron beams of the SEM system.

8. The detector of claim 2, wherein the plurality of sensing elements include at least 1000 PIN diodes.

9. A charged-particle inspection system comprising:
a charged-particle beam source configured to generate a primary charged-particle beam for sample scanning; and
a detector configured to receive a secondary charged-particle beam exiting a sample from a point of incidence of the primary charged-particle beam at the sample, the detector comprising:
a semiconductor substrate; and
a switching network formed on the semiconductor substrate and comprising a radiation hardened NMOS transistor, the NMOS transistor comprising a first source/drain diffusion region, a second source/drain diffusion region, and a gate patterned on the semiconductor substrate and encircling one of the first and second source/drain diffusion regions.

10. The charged-particle inspection system of claim 9, wherein the detector further comprises a plurality of sensing elements formed on the semiconductor substrate.

11. The charged-particle inspection system of claim 10, wherein the switching network has a plurality of input terminals connecting to a different sensing element of the plurality of sensing elements.

12. The charged-particle inspection system of claim 10, wherein the switching network has a common node communicatively coupled with a group of sensing elements among the plurality of sensing elements and configured to connect, via a chip-to-chip connection, to a read-out channel of a readout substrate.

13. The charged-particle inspection system of claim 12, wherein each sensing element of the plurality of sensing elements is configured to generate an electrical signal in response to electrons incident on the each sensing element, and the switching network is configured to combine electrical signals generated from the group of sensing elements and to transmit the combined electrical signals to the read-out channel via the common node.

14. The charged-particle inspection system of claim 10, wherein the switching network is configured to transmit an electrical signal from each group of multiple groups of the plurality of sensing elements, via a chip-to-chip connection, to a corresponding read-out channel of a readout substrate having multiple read-out channels corresponding to the multiple groups.

15. The charged-particle inspection system of claim 14, wherein each group of the multiple groups is associated with a different secondary electron beam of a plurality of secondary electron beams of the SEM system.

16. A readout integrated circuit for a scanning electron microscope (SEM) system, comprising:
a semiconductor substrate; and
a plurality of transistors formed on the semiconductor substrate and configured to form a switching network, the switching network having a plurality of input terminals each configured to connect, via a chip-to-chip connection, to a different sensing element of a plurality of sensing elements of another substrate, and the switching network having a common node communicatively coupled with a group of sensing elements among the plurality of sensing elements.

17. The readout integrated circuit of claim 16, further comprising a readout channel formed on the semiconductor substrate,
wherein each sensing element of the plurality of sensing elements is configured to generate an electrical signal in response to particles incident on the each sensing element, and the switching network is configured to combine electrical signals generated from the group of sensing elements and to transmit the combined electrical signals to the readout channel via the common node.

18. The readout integrated circuit of claim 16, further comprising multiple readout channels corresponding to multiple groups,
wherein the switching network is configured to transmit an electrical signal from each group of multiple groups of the plurality of sensing elements to a corresponding readout channel among the multiple readout channels.

19. The readout integrated circuit of claim 18, wherein each group of the multiple groups is associated with a different secondary electron beam of a plurality of secondary electron beams of the SEM system.

20. The readout integrated circuit of claim 16, wherein the plurality of sensing elements include at least 1000 PIN diodes.
